(19) United States
(12) Patent Application Publication
(10) Pub. No.: US 2005/0162892 A1
(43) Pub. Date: Jul. 28, 2005

(54) One-time programmable memory cell

(76) Inventors: Michel Bardouillet, Rousset (FR); Pierre Rizzo, Aix En Provence (FR); Alexandre Malherbe, Trets (FR); Luc Wuidart, Pourrieres (FR)

Correspondence Address: WOLF GREENFIELD & SACKS, PC;FEDERAL RESERVE PLAZA, 600 ATLANTIC AVENUE, BOSTON, MA, 02210-2211, US

(21) Appl. No.: 10/504,203

(22) PCT Filed: Feb. 11, 2003
(86) PCT No.: PCT/FR03/00447

(30) Foreign Application Priority Data
Feb. 11, 2002 (FR) 02/01644
Oct. 29, 2002 (FR) 02/13557

(51) Int. Cl. G11C 11/00

(52) U.S. Cl. 365/148

(57) ABSTRACT

The invention relates to a memory cell with a binary value consisting of two parallel branches. Each of said branches comprises: at least one polycrystalline silicon programming resistor (Rp1, Rp2), which is connected between a first supply terminal (1) and a point or terminal for the differential reading (4, 6) of the memory cell state; and at least one first switch (MNP1, MNP2) which, during programming, connects one of said read terminals to a second supply terminal (2).

The present invention relates to the field of one-time programming memory cells (OTP) and more specifically to the forming of a one-time programming memory which enables storage of a binary code in an integrated circuit, without for this code to be observable.

Presently, to form a one-time programming memory, elements of fuse type formed of polysilicon tracks can be used. Such fuses have the disadvantage of having an optically-detectable state (off or on). Indeed, a polysilicon fusible element is destroyed by being submitted to a current on the order of one tenth of an ampere, which generates a physical deterioration of the conductive track forming it. Another disadvantage is that the strong necessary current imposes destroying the fuse upon manufacturing and is little compatible with the forming of a one-time programming memory cell, the programming of which may be performed during the product lifetime.

A second known category of one-time programming memories is formed of EPROMs. These memories have the disadvantage of requiring transistors (floating-gate transistors) which generate additional manufacturing steps with respect to the steps of standard MOS technologies. Another disadvantage is that the content of such a memory cell is observable, out of operation, by examining the charges contained in this cell, that is, by means of an electronic scanning microscope. Indeed, the number of charges in the floating gates of the transistors is different according to the memory cell programming. This difference in the number of charges can be detected by an electronic scanning microscope, which adversely affects the storage impregnability. There are also one-time programming memories formed by EEPROMs and non-erasable flash memories, which exhibit similar disadvantages.

Another disadvantage of EPROMs is that they are sensitive to ultraviolet rays.

An example of application of the present invention relates to the field of smart cards in which binary codes must be stored without risking to be pirated. The codes may represent transaction algorithm keys or any other encryption, identification, or authentication key. More generally, the present invention applies to any system in which a binary word is desired to be irreversibly programmed (that is, by a single programming), or at least programmed a limited number of times, in an integrated circuit, without for the result of this programming to be observable.

The present invention aims at providing a novel one-time programming memory structure which exhibits these features.

The present invention also aims at providing a one-time programming memory cell that can be programmed after manufacturing of the integrated circuit, while said circuit is in its application environment.

The present invention also aims at providing a memory cell, the programming of which is not observable, be it optically or, out of operation, by electronic scanning microscope.

The present invention also aims at providing a one-time programming memory cell that can be formed in the same technology as the MOS transistors of the integrated circuit to which it is added, and without being sensitive to ultraviolet rays.

The present invention also aims at providing a memory based on such cells which is compatible with a differential structure.

To achieve these and other objects, the present invention generally provides a binary value memory cell, comprising:
two parallel branches, each comprising at least one polysilicon programming resistor connected between a first supply terminal and a differential cell state read point or terminal; and
at least one first switch connecting, during a programmation, one of said read terminals to a second supply voltage terminal.

According to an embodiment of the present invention, each branch comprises a first switch connecting, during a programmation, the branch read terminal to a second supply terminal.

The present invention also provides a binary value memory cell, comprising:
two parallel branches, each comprising, in series between two supply voltage terminals, a programmation resistor in polysilicon, and a fixed resistor, the fixed resistors of the two branches being, preferentially, identical;
a differential amplifier, the respective inputs of which are connected to the central points between the resistors of each branch constituting differential reading points of the cell state, the output of the amplifier providing the binary value storage in the cell; and
at least a first switch short-circuiting, during a programmation, one of said fixed resistors.

The invention also provides a binary value memory cell, comprising:
two parallel branches, each comprising, in series between two supply voltage terminals, a programmation resistor made of polysilicon, a first transistor and a second transistor, the junction between the resistor and the first transistor defining a direct or reverse read terminal of the binary value stored in the cell, the gates of the second transistors receiving a cell selection signal and the gate of the first transistor of each branch being connected to the read point of the other branch; and
at least a first switch connecting, during a programmation, one of said read terminals to one of said supply voltage terminals.

The present invention also provides a binary value memory cell, comprising:
two parallel branches, each comprising, in series between a first supply terminal and a differential read point or terminal of the state of the cell, a programmation resistor in polysilicon, and a first transistor, two first switches connecting each of said respective read terminals to a second supply voltage terminal.

The present invention also provides a binary memory cell comprising:
two parallel branches, each comprising, in series between two supply voltage terminals, a first transistor, two programmation resistors in polysilicon and a second transistor, the gate of the second transistor of each branch being connected to the interconnection between one of the terminals and the second transistor of the other branch;
a differential amplifier, the two respective inputs of which are connected to the junction between the resistors of each branch and two inverted outputs of which are respectively connected to the gates of the first transistors; and
at least a first switch short-circuiting, during a programmation, one of said second transistors.

According to an embodiment of the present invention, one of the supply voltage terminals is connected, through a selector, to at least two supply voltages among which a read supply voltage relatively low and a programmation supply voltage relatively high.

The present invention also provides a binary value memory cell, comprising:
two parallel branches, each comprising, in series between a first read voltage terminal and a reference potential terminal, a first transistor, a programmation resistor made of polysilicon, and a second transistor, the junction between the resistor and the first transistor of each branch defining a read point of the differential state of the cell connected to the gates of the transistors of the other branch; and
at least two first switches for applying, during a programmation, a programmation potential to one of said read terminals.

According to an embodiment of the present invention, two second switches for selection are inserted between said read points and the respective first switch connected thereto.

According to an embodiment of the present invention, a supply switch connects said first terminal to a read voltage supply terminal for interrupting the power consumption of the cell once the state is generated.

According to an embodiment of the present invention, third two transistors connect the gate of the first and second transistors of the respective terminal to the reference potential terminal, for stabilizing the generated state.

According to an embodiment of the present invention, said supply switch and said third transistors are simultaneously controlled.

According to an embodiment of the present invention, said programmation resistors have the same size and the same possible doping.

According to an embodiment of the present invention, the programmation is made by reducing, in an irreversible and stable way within the operation read current range of the cell, the value of one of the programmation resistors by flowing a current in one current in one of the resistors made of polysilicon that is higher than the current for which the value of said resistor has a maximum, the programmation being not destructive of said resistor.

The present invention also provides a one-time programming memory comprising a plurality of memory cells sharing same first switches.

The present invention also provides a method for programming a memory cell, consisting temporarily of imposing, in one of said branches selected by one of the first switches, a current higher than the current for which the value of the programmation resistor of the relative branch has a maximum.

According to an embodiment, the present invention comprises the following steps:
increasing step by step the current in the programming resistor selected by the programming switch of one of the branches; and
measuring, after each application of a greater current, the value of this resistance in its functional read environment.

According to an embodiment of the present invention, a predetermined table of correspondence between the programming current and the desired final resistance to apply to the selected programming resistor the adapted programming current.

The foregoing objects, features and advantages of the present invention, will be discussed in detail in the following non-limiting description of specific embodiments in connection with the accompanying drawings, in which:

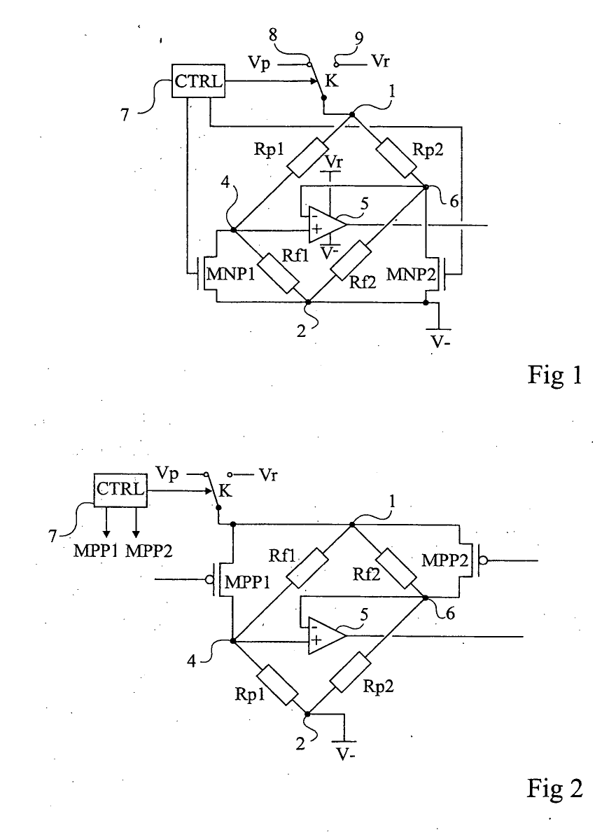

FIG. 1 shows the electric diagram of a one-time programming memory cell according to a first embodiment of the present invention;

FIG. 2 shows the electric diagram of a one-time programming memory cell according to a second embodiment of the present invention;

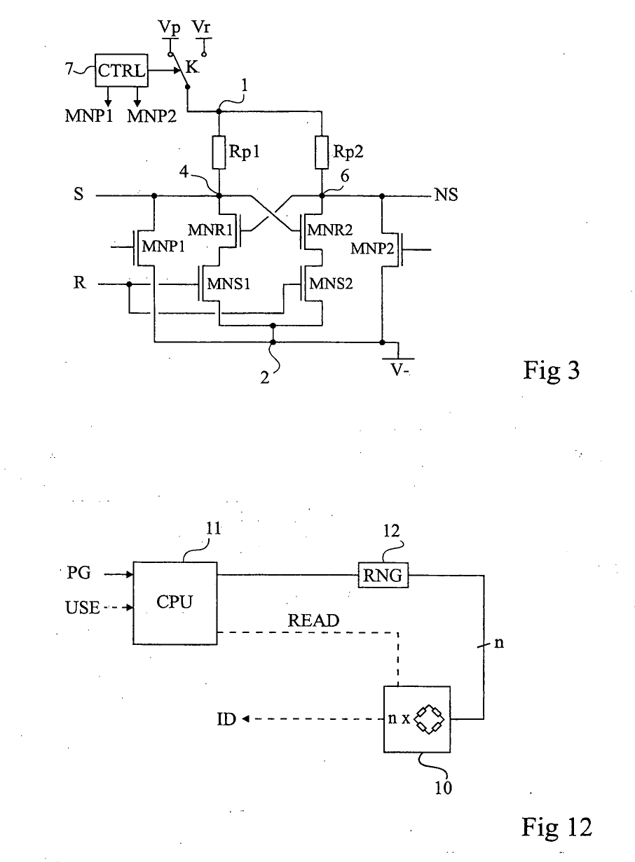

FIG. 3 shows the electric diagram of a one-time programming memory cell according to a third embodiment of the present invention;

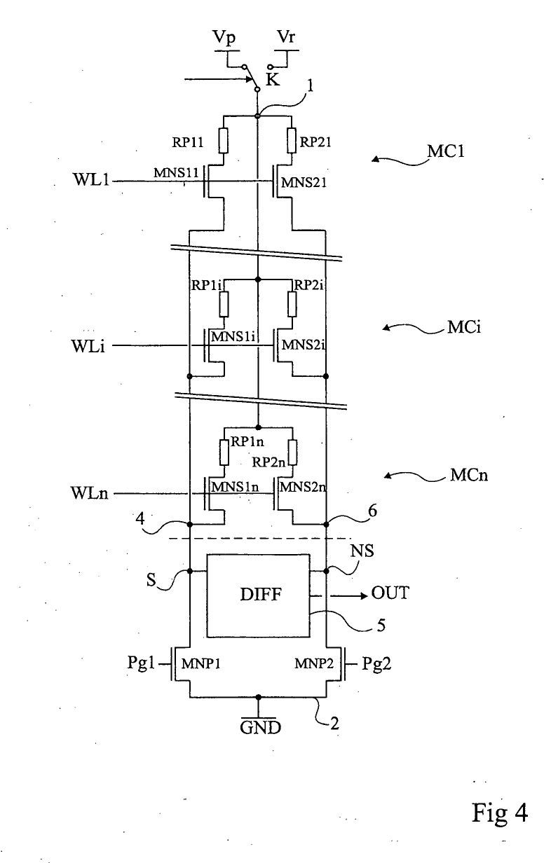

FIG. 4 shows the electric diagram of a memory cell column according to a fourth embodiment of the present invention;

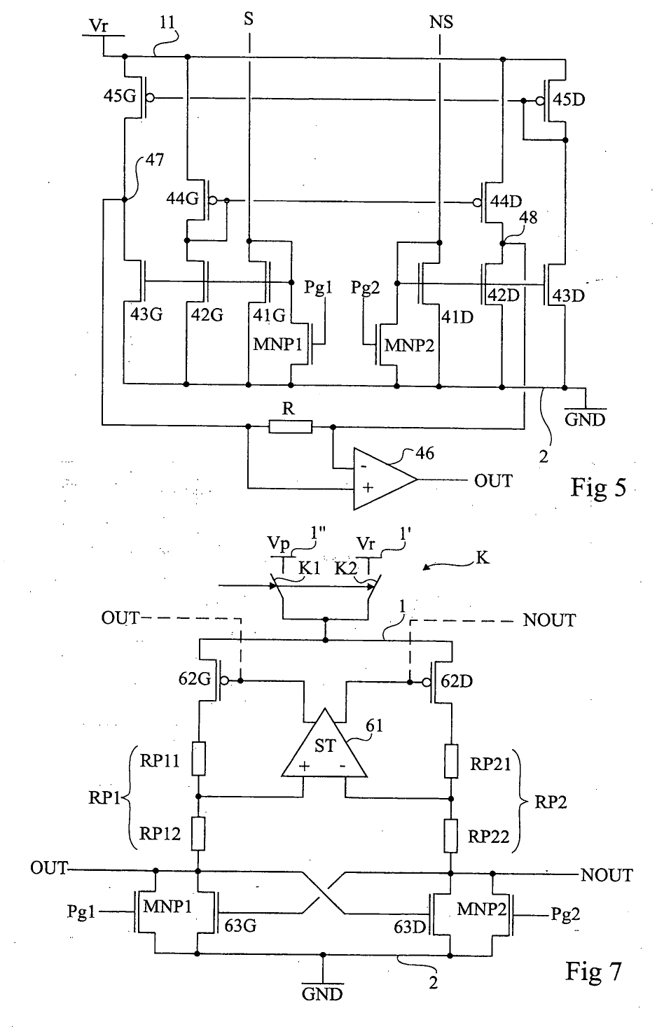

FIG. 5 shows the electric diagram of an embodiment of the differential read amplifier of FIG. 4;

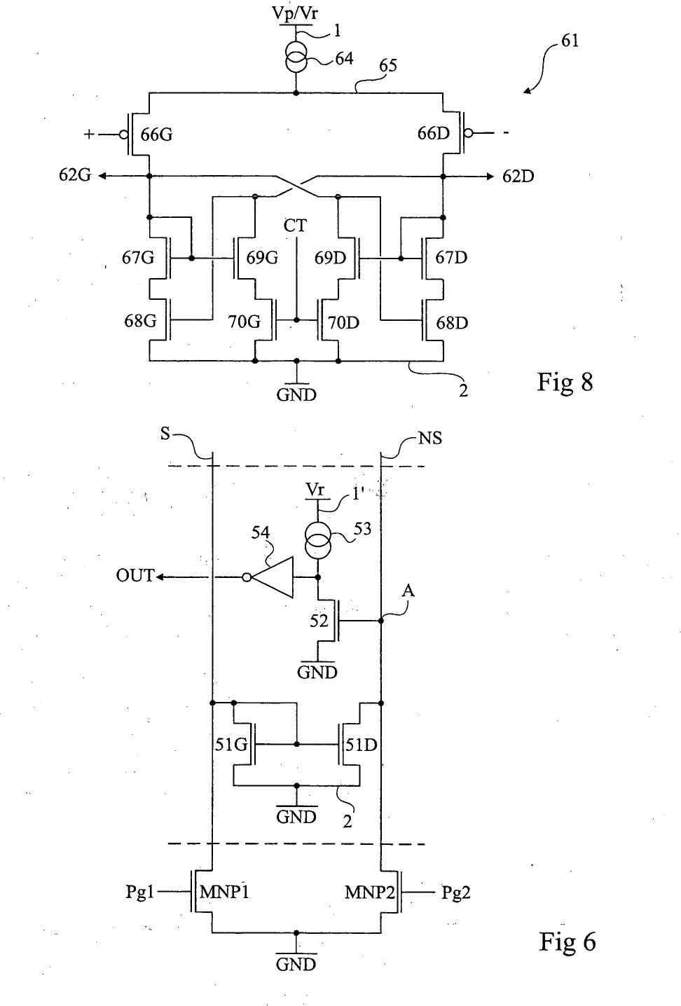

FIG. 6 shows the electric diagram of another embodiment of the differential read circuit of FIG. 4;

FIG. 7 shows the electric diagram of a one-time programming memory cell according to a fifth embodiment of the present invention;

FIG. 8 shows an example of implementation of an amplifier with a Schmitt trigger used in the embodiment of FIG. 7;

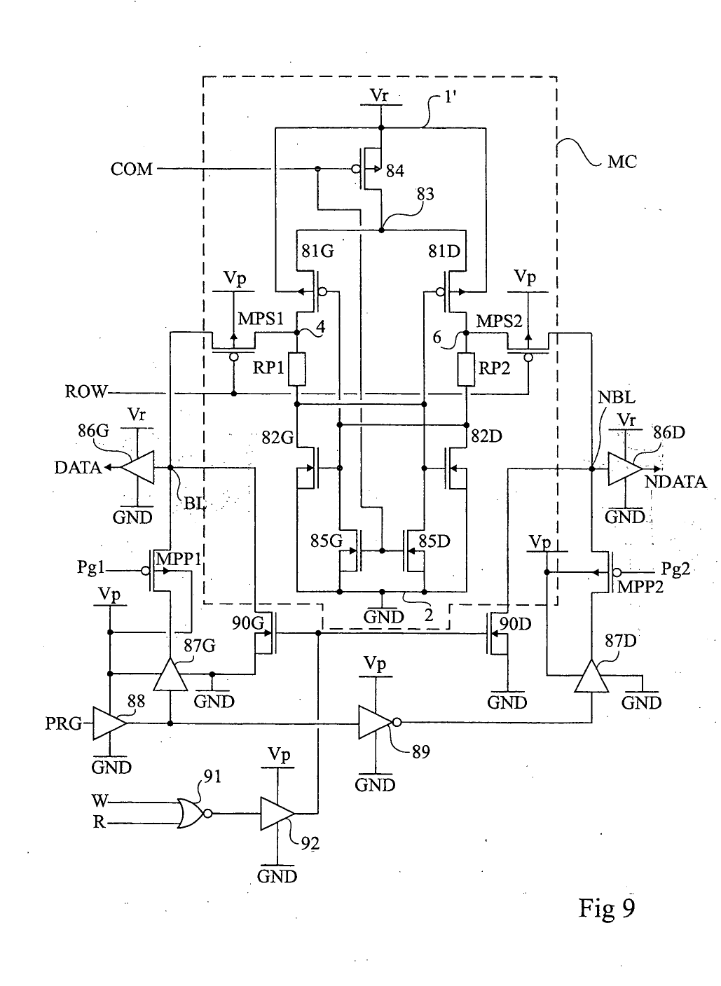

FIG. 9 shows the electric diagram of a one-time programming memory cell according to a sixth embodiment of the present invention;

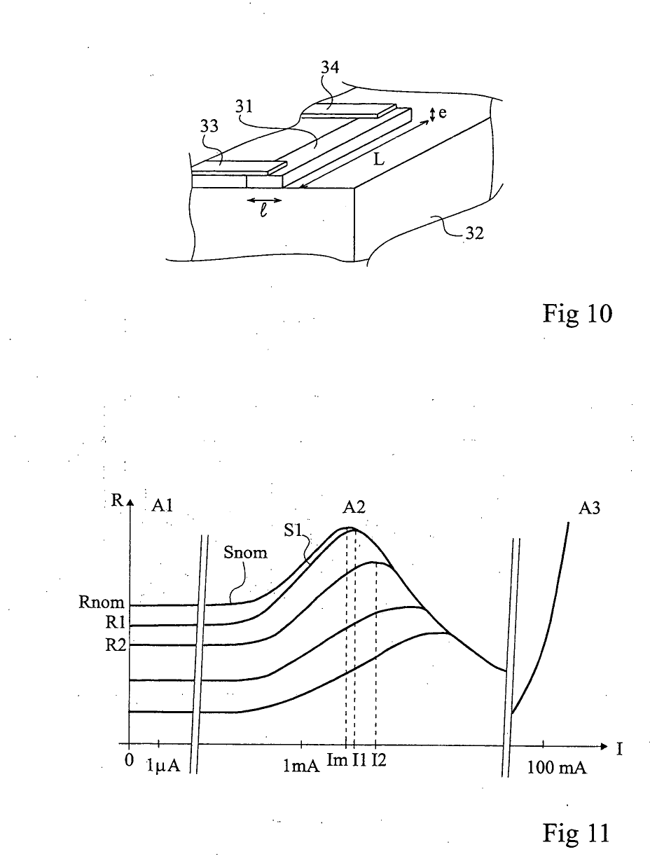

FIG. 10 shows, in a partial very simplified perspective view, an embodiment of a polysilicon resistor constitutive of a memory cell according to the present invention;

FIG. 11 illustrates, in a curve network, the programming of a memory cell according to an implementation mode of the present invention; and

FIG. 12 very schematically shows in the form of blocks an example of application of the present invention to the generation of an integrated circuit identifier.

The same elements have been designated with the same references in the different drawings. For clarity, only those elements that are necessary to the understanding of the present invention have been shown in the drawings and will be described hereafter. In particular, the different circuits for reading and exploiting the binary codes stored in a memory cell according to the present invention have not been detailed. The present invention can be implemented whatever the exploitation made of the binary code stored in one or several of these memory cells.

A feature of a memory cell according to the present invention is that it comprises two resistive branches in parallel. Each branch is formed of at least one programmable polysilicon resistor.

FIG. 1 shows a first embodiment of a memory cell according to the present invention.

According to this embodiment, each resistive branch is formed of two resistors in series, the measurement of a memorized level being performed by connecting the midpoints of the series associations to the respective inputs of a differential amplifier. The non-programmable resistor of each branch can be short-circuited by means of a programming switch.

A first branch of the memory cell comprises, in series between two terminals 1 and 2 of application of a supply voltage, a first programmable resistor Rp1 and a first fixed resistor Rf1. A second branch of the memory cell comprises, in series between terminals 1 and 2, a second programmable resistor Rp2 and a second fixed resistor Rf2. Junction point 4 of resistors Rp1 and Rf1 is connected to a first (for example, non-inverting) input of a differential read amplifier 5. Junction point 6 of resistors Rp2 and Rf2, is connected to the other (for example, inverting) input of differential amplifier 5. The output of differential amplifier 5 provides state 0 or 1 stored in the memory cell.

It can be seen that, if resistors Rf1 and Rf2 are of same value, the slightest difference between resistors Rp1 and Rp2 conditions the output state of read amplifier 5. In other words, in the example shown, if resistance Rp1 is greater than resistance Rp2, the voltage at point 6 is greater than the voltage at point 4. This results in a zero state (level V-) at the output of amplifier 5. In the opposite case (resistance Rp1 smaller than resistance Rp2), point 4 is at a greater voltage than point 6. This results in a high level at the output of amplifier 5 and thus in a state 1.

According to the present invention, at least one switch (in this example, an N-channel programming MOS transistor MNP1 or MNP2) connects each programmable resistor (points 4 and 6) to terminal 2. Terminal 2 is a terminal of application of a reference supply voltage V—(for example, the ground). Transistors MNP1 and MNP2 are individually controllable by a programming circuit 7 (CTRL). On the positive supply side (terminal 1), the operating (read) voltage Vr is, according to this embodiment, different from a programming voltage Vp. The selection between the two voltages is performed, for example, by means of a selector K having a terminal connected to positive supply terminal 1 of the memory cell. The two other terminals 8 and 9 of switch K are respectively connected to terminals of application of programming and read voltages Vp and Vr. In the example shown, amplifier 5 is supplied by read voltage Vr. This voltage is preferably such that the current in the cell is smaller than some hundred microamperes and more specifically on the order of from 1 to 10 microamperes.

According to the present invention, resistors Rp1 and Rp2 are identically formed, that is, they are formed of polysilicon tracks having identical dimensions and identical dopings. Resistors Rf1 and Rf2 are also preferentially identical. The programming performed by the present invention is used to cause an imbalance between programming resistors Rp1 and Rp2 as will be explained hereafter.

A feature of the present invention is to provide a programming of the memory cell by causing an irreversible decrease in the value of one of programming resistors Rp1 or Rp2 according to the desired state, by forcing the flowing of a current through the resistor to be programmed, which is greater than the current for which the resistance exhibits a maximum. This feature of the present invention will be better understood hereafter in relation with FIGS. 10 and 11. For the time being, it will only be said that transistor MNP1 enables short-circuiting resistor Rf1 and running, through resistor Rp1, a current imposed by the level of programming voltage Vp which results in decreasing its value. As for transistor MNP2, it is used, for the other branch, to short-circuit resistor Rf2 and decrease the value of resistor Rp2 when said resistor is supplied by programming voltage Vp. According to that of resistors Rp1 or Rp2 having had its value decreased with respect to the other, the state stored in the cell is different. According to this embodiment of the present invention, the programming voltage (capable of generating a current, for example, on the order of from one to 10 milliamperes) is greater than the read voltage so that the programming current is located beyond the memory cell operating current range (up to 100 microamperes).

Transistors MNP1 and MNP2 here also enable protecting resistors Rf1 and Rf2 when the memory cell is supplied by voltage Vp substantially greater than voltage Vr. They then avoid, if resistors Rf1 and Rf2 are made of polysilicon, modifying their values upon programming.

Initially (just after manufacturing), the state of the memory cell is undetermined, provided that resistors Rp1 and Rp2, respectively Rf1 and Rf2, have identical dimensions.

As an alternative, the original value (before programming of resistors Rp1 and Rp2) may be pre-programmed by providing different values for resistors Rf1 and Rf2. Such an alternative enables, knowing the unprogrammed state of the cells, only using a single programming transistor to decrease resistance Rp1 or Rp2 of the branch containing the smallest resistance Rf1 or Rf2. Of course, account must then be taken, for the choice of resistances Rp1 and Rp2, of the difference between the values of resistors Rf1 and Rf2 and of the value decrease which will be performed to program the cell.

The state programmed in a memory cell according to the present invention is observable neither optically, nor by means of an electronic scanning microscope. Indeed, conversely to the charge accumulation performed in a floating gate, the programming performed by the present invention is invisible since it only modifies the value of one of the polysilicon resistors, without for it to be permanently charged. Further, this modification characteristic of the present invention is non-destructive, conversely to a fusible operation which consists of physically deteriorating the structure of a polysilicon resistor. It is thus also optically invisible.

Another advantage of the present invention which already appears from the foregoing description is that the level stored in a memory cell is not observable by attacks of electric power analysis type. Indeed, the current signature (current consumption) of the memory cell is independent from the stored state, the equivalent resistance of the two branches in parallel being the same, whatever that of resistors Rp1 or Rp2 which has seen its value decrease to set the programmed state.

FIG. 2 shows, in a view to be compared with that of FIG. 1, a second embodiment of a one-time programming memory cell according to the present invention. The only difference between the two embodiments is that, in FIG. 2, a programming by means of two P-channel MOS transistors MPP1 and MPP2 instead of two N-channel MOS transistors is provided. This amounts to turning over the structure with respect to supply terminals 1 and 2. In other words, fixed resistors Rf1 and Rf2 connect positive supply terminal 1 to respective drains 4 and 6 of transistors MPP1 and MPP2. Programming resistors Rp1 and Rp2 respectively connect points 4 and 6 to reference supply terminal 2. Transistors MPP1 and MPP2 are individually controlled by circuit 7, which also controls the position of switch K selecting the programming or read operating mode. Although this has not been shown in FIG. 2, differential amplifier 5 is still supplied by voltage Vr.

Functionally, the only difference between FIGS. 1 and 2 is that the control levels provided by circuit 7 are inverted for transistors MPP1 and MPP2 due to their type of channel.

The embodiment of FIG. 1 however is a preferred embodiment due to the smaller bulk of N-channel MOS transistors as compared to P-channel transistors.

FIG. 3 shows a third embodiment of a one-time programming memory cell according to the present invention.

Like for the two other embodiments, the cell comprises two resistive branches in parallel between two supply terminals 1 and 2, and two programming switches MNP1 and MNP2 (in this example, N-channel MOS transistors), a control circuit 7, and a selector K between two supply voltages, respectively for reading, Vr, and for programming, Vp. The programming of a cell such as illustrated in FIG. 3 is similar to that of the cells of FIGS. 1 and 2. What here changes is the structure of the cell to enable reading thereof.

A feature of this embodiment is to integrate the differential read amplifier in the resistive branches, thus avoiding use of fixed resistors Rf1 and Rf2. In the embodiment of FIGS. 1 and 2, resistors Rf1 and Rf2 may be made in the form of MOS transistors.

In the embodiment of FIG. 3, a first so-called left-hand branch in the orientation of the drawing comprises, in series, resistor Rp1, a read MOS transistor MNR1, and a selection MOS transistor MNS1. The interconnection between resistor Rp1 and transistor MNR1 (and thus the drain of this transistor) forms a first output terminal S, arbitrarily called the “direct” (non-inverted) output terminal. Terminal S also corresponds to point 4 of connection of resistor Rp1 to programming transistor MNP1. A second so-called right-hand branch in the orientation of the drawing comprises, in series, resistor Rp2, a read MOS transistor MNR2, and a selection MOS transistor MNS2. The interconnection between resistor Rp2 and transistor MNR2 (and thus the drain of this transistor) forms a second terminal NS, which is the inverse of terminal S. Terminal NS also corresponds to point 6 of connection of resistor Rp2 to programming transistor MNP2. The gate of transistor MNR2 is connected to terminal 4 while the gate of transistor MNR1 is connected to terminal 6 to obtain the effect of a bistable. The gates of transistors MNS1 and MNS2 are connected together to a terminal R intended to receive a read selection signal of cell 1. This signal preferably corresponds to the cell selection signal in an array arrangement of several memory cells. It is then provided by the column or line decoder. In the example shown, all transistors are N-channel transistors.

The read operation of a cell according to this embodiment is the following. Control circuit 7 switches selector K to voltage Vr. Preferably, this is its quiescent state since the other state is used in programming only (and thus, in principle, only once). Input terminal R receives a signal (active in the high state) of cell selection (or configuration in read mode), turning on both transistors MNS1 and MNS2.

As a result, one of terminals S and NS sees its voltage increase faster than the other. This imbalance is due to the difference between resistances Rp1 and Rp2. It turns on one of transistors MNR1 and MNR2. Due to the crossing of the gates of these transistors, that which is on first is that whose gate takes part in the electric path (from terminal 1) having the smallest time constant (the resistor with the smallest value generates a smaller time constant), and thus that whose drain voltage increases slower than the other. Once on, this transistor MNR forces its drain (and thus the corresponding output terminal S or NS) to ground, which confirms the blocking of the MNR transistor of the other branch, and thus the high state on the corresponding output terminal.

The programming of a cell according to this embodiment is performed in the same way as for the first two embodiments by means of transistors MNP1 and MNP2. However, transistors MNS1 and MNS2 of the cell must be turned off in the programming (low input R). They are used to protect read transistors MNR1 and MNR2 by making their sources float. By disconnecting the MNR transistors by their sources, the MNS transistors prevent them from seeing high voltage Vp between their drain and source. Accordingly, the MNR and MNS transistors can be sized according to read voltage Vr. Only the MNP programming transistors need sizing to stand voltage Vp and stand the relatively high current (as compared to the read operating current range) used to program the cell.

An advantage of this embodiment is that it combines the storage cell and its read amplifier.

Like for the embodiments of FIGS. 1 and 2, the embodiment of FIG. 3 applies to N-channel MOS transistors (shown embodiment) or to P-channel transistors. Transposing the embodiment of FIG. 3 to P-channel MOS transistors is within the abilities of those skilled in the art.

According to an alternative embodiment, a single supply voltage may be used for the memory cell. The selection of the supply voltage between levels Vp and Vr is thus avoided. In this case, a supply voltage sufficient to impose the desired constraint to the programming of resistors Rp1 and Rp2 is chosen (FIGS. 1, 2, and 3). The values of resistors Rf1 and Rf2 (FIGS. 1 and 2) or the dimensions of transistors MNS1, MNS2, MNR1 and MNR2 (FIG. 3) are then chosen accordingly (for examples, sufficiently high resistances Rf1 and Rf2 to impose across the programming resistors a sufficiently low voltage ensuring operation in a current range below some ten or hundred microamperes). Such an embodiment is however not a preferred embodiment since it imposes a relatively significant permanent current consumption.

FIG. 4 illustrates a memory cell column MC1, . . . MCi, . . . MCn according to a fourth embodiment of the present invention. This drawing illustrates the possibility of association of the memory cells with a programming resistor specific to the present invention in an array network. For simplification, FIG. 4 shows a single column. It should however be noted that several parallel columns may be provided.

Each memory cell MCi of the column is formed of two parallel branches, each comprising, between a terminal 1 of application of a supply voltage and a respective output terminal 4 or 6 intended to be read by a differential read element 5, a programmable resistor RP1i, respectively RP2i, and a switch (here, an N-channel MOS transistor) MNS1i, respectively MNS2i, for selecting the column cell. Terminals 4 and 6, corresponding to terminals S and NS of input of differential amplifier 5 or of output of the memory arrangement, are respectively connected to second terminal 2 of application of the supply voltage (for example, ground GND) via programming transistors MNP1 and MNP2.

The different memory cells MCi are thus in parallel between terminal 1 and terminals 4 and 6. In the example shown, terminal 1 is connected to supply voltages (lines 1″ and 1′) respectively for reading Vr and for programming Vp via a switch K controlled by a control circuit (not shown) according to whether a read or programming operation is desired.

In the example shown, programming transistors MNP1 and MNP2 receive respective signals Pg1 and Pg2 from the control circuit. As an alternative, and as will be seen hereafter in relation with some of the embodiments of the differential amplifier, signals Pg1 and Pg2 may be one and the same programming control signal.

In the circuit of FIG. 4, selection transistors MNS1i and MNS2i of each memory cell are controlled together by respective word line selection signals WLi. This word line notation is used referring to the usual designations of lines and columns in a memory plane. As an alternative, the line selection signals WLi may be divided into two separate signals of selection of a branch with respect to the other, especially if this is required for the programming of one of the two branches while a single programming control signal is used simultaneously for transistors MNP1 and MNP2.

From the foregoing discussion, one can see that each memory cell comprises, in parallel between two terminals of application of the supply voltage, two branches each comprising a polysilicon resistor, and at least one programming switch connecting each resistor to the second supply terminal. Due to the need for selection of the memory lines, a second switch is connected in series between the programming transistor and the resistor. Said switch is transistor MNS of selection of the involved cell.

Different examples of forming of differential read elements 5 will be described hereafter in relation with FIGS. 5 and 6. The selection transistors have been omitted therein due to the singleness of the read element for an entire column of memory cells such as illustrated in FIG. 4.

Programming transistors MNP1 and MNP2 have been shown to better show the link with FIG. 4. It should however be noted that they do not actually belong to the differential read elements.

FIG. 5 shows a first example of a differential read amplifier 5 detecting a current difference between the two branches of a memory cell.

The diagram of FIG. 5 is based on the use of two transconductance amplifiers each comprising at least two parallel current mirror branches. In the example shown, three branches in parallel are provided for each of the output branches (S and NS) of the memory cell.

For example, on the side of terminal S (arbitrarily on the side of the left-hand branch in the orientation of the drawing), each branch comprises a transistor 41G, 42G, and 43G, respectively (for example, N-channel MOS transistors), assembled as current mirrors. Transistor 41G connects terminal S to ground 2 and is diode-assembled, its gate and its drain being interconnected. Transistor 42G of the second branch is connected by its source to terminal 2 and by its drain to the drain of a P-channel MOS transistor 44G, the source of which is connected to read voltage supply line 1″. On the third branch side, transistor 43G is connected to supply line 1″ via a P-channel MOS transistor 45G, the source of transistor 43G being connected to ground 2.

The same structure is reproduced on the right-hand side of the drawing for the connection of terminal NS. Transistor 41D of the first branch is still diode-assembled. Transistor 44D of the second branch has its gate connected to that of transistor 44G on which it is assembled as a current mirror, transistor 44G being diode-assembled, with its gate connected to its drain. On the third branch side, transistor 45D is diode-assembled with its gate connected to its drain, and its gate is connected to the gate of transistor 45G of the left-hand branch.

The differential measurement is performed by means of an operational amplifier 46, the respective inverting and non-inverting inputs of which are connected to points 47 and 48 of interconnection of transistors 45G, 43G of the third left-hand branch and 44D and 42D of the second right-hand branch. Further, a measurement resistor R connects the input terminals of amplifier 46. Output OUT of amplifier 46 provides the state of the read memory cell.

An advantage of the embodiment of FIG. 5 is that it enables getting rid of possible dissymmetries of the structures of the selection MOS transistors and, more specifically, of dissymmetries between the capacitances present in the circuit. It thus is a pure resistance measurement amplifier.

It should be noted that, like for the supply of amplifier 46 of FIG. 5, only read voltage Vr supplies the current mirrors.

FIG. 6 shows another example of a differential read amplifier applicable to the memory cells of FIG. 4. The reading is here performed on the voltage. The amplifier is formed of two MOS transistors (here, with an N-channel, 51G and 51D) respectively connecting terminals S and NS to ground 2, one of the transistors (for example, 51G) being diode-assembled and the gates of transistors 51G and 51D being interconnected. It thus is a current mirror balancing the voltages between terminals S and NS in read mode. The current mirror amplifies the difference, the left-hand branch setting the current for the other branch. Accordingly, if the resistance of the left-hand branch S of the selected memory cell is smaller than the right-hand resistance of this cell, a stronger current flows through this left-hand branch. Since the mirror transistor of the other branch applies the same current, the fact for its memory cell resistance to be stronger results in voltage read point A falling to a low voltage (the ground, neglecting the series resistances of the transistors in the on state). Point A is connected to the gate of a read MOS transistor 52, connected in series with a constant current source 53 between terminal 1′ of application of read voltage Vr and ground 2. The point of interconnection between transistor 52 and terminal 53 may cross an inverter 54, the output terminal of which provides the state of the selected cell. When point A is at a voltage close to ground, transistor 52 is off. In the opposite case, this transistor is on. A switching of output OUT of the differential read amplifier is thus effectively obtained.

According to an alternative embodiment, the read point (gate of transistor 52) is connected to line S provided that, this time, transistor 51D of the line is diode-assembled.

Like for the assembly of FIG. 5, when a programming of one of the memory cells is desired to be performed, said cell is selected by means of its signal WLi (FIG. 4) and the transistor MNP1 or MNP2 of the branch in which the value of the programming polysilicon resistor is desired to be decreased is turned on.

FIG. 7 shows a fifth embodiment of a one-time programming memory cell according to the present invention. This cell is based on the use of a hysteresis comparator or amplifier (commonly called a Schmitt trigger) 61 forming at the same time a differential read element.

Like for the other embodiments, the cell comprises two parallel branches comprising, each in series between terminals 1 and 2 of application of a supply voltage, a resistive programmable element RP1, RP2 and at least one switch forming a programming transistor MNP1, MNP2. In the example of FIG. 7, each branch also comprises, for its reading, a P-channel MOS transistor 62G, 62D connecting terminal 1 to a first terminal of resistive element RP1, RP2, respectively, and an N-channel MOS transistor 63G, 63D respectively connecting the other terminal of resistive element RP1, RP2 to ground 2. The respective gates of transistors 63G and 63D are connected to the drain of the opposite transistor, that is, to the respective drains of programming transistors MNP1 and MNP2.

Resistive elements RP1 and RP2 are each formed of two resistors in series RP11, RP12 and RP21, RP22, the respective junction points of which are connected to the non-inverting and inverting inputs of Schmitt trigger 61. The respective outputs of the Schmitt trigger are connected to the gates of transistors 62G and 62D.

Positive terminal 1 is connected to voltages Vp and Vr by means of a switch circuit K. Here, an alternative switch circuit has been illustrated in the form of two switches K1 and K2 respectively connecting terminals 1′ and 1″ of application of voltages Vr and Vp to terminal 1. Of course, switches K1 and K2 are not simultaneously on.

In read mode, as soon as the cell is supplied under voltage Vr, Schmitt trigger 61 turns on the two transistors 62G and 62D. The flip-flop assembly of the bottom of the cell (transistors 63G and 63D) detects the imbalance between resistors RP1 and RP2. Trigger 61 reads this imbalance and turns off transistor 62G or 62D of the branch having the highest resistance value RP1 or RP2.

An advantage of the memory cell of FIG. 7 is that once the reading has been performed, no current flows through the cell.

Another advantage of the presence of trigger 61 is that it enables detection of a small imbalance without waiting for flip-flop 63G, 63D to have completely turned off one of transistors 63G and 63D.

In the example shown, the respective direct and inverse outputs OUT and NOUT of the cell are formed by the gates of transistors 63D and 63G. As an alternative and as illustrated in dotted lines in FIG. 7, the gates of transistors 62G and 62D (the outputs of the Schmitt trigger) may also be used as cell outputs.

The programming of a memory cell such as illustrated in the drawing is performed in two steps. In a first step, one of the programming transistors (for example, MNP2) is turned on by signal Pg2. The imbalance then introduced turns off transistor 62D and turns on transistor 62G. This state is steady since a smaller resistance is imposed on the left-hand branch.

In a second step, it is switched to programming voltage Vp by means of switches K1 and K2, and programming switch MNP1 is turned on by means of signal Pg1 to force this current to flow through the left-hand branch and thus program, by decreasing their values, resistors RP11 and RP12. No current flows through the right-hand resistors due to the off state of transistor 62D which isolates it from the programming voltage.

If the cell is desired to be programmed in the other way, the operation discussed hereabove is reversed. Schmitt trigger 61 is then not only used in read mode to avoid the cell consumption, but also to select the branch to be programmed.

According to an alternative embodiment where an initial (manufacturing) state of the cell is only desired to be confirmed, signals Pg1 and Pg2 may be one and the same, and the programming then confirms the initial state by decreasing resistance RP1 or RP2 which, in the state just after manufacturing, already exhibits a slightly lower value.

It should be noted that the embodiment of FIG. 7 is compatible with the use of a single supply voltage, said voltage being then set to the level of programming voltage Vp. Indeed, in read mode, as soon as the state is confirmed by the Schmitt trigger, there is no risk of programming the resistors since there is no more current. To achieve this, it must be ascertained that the read current does not last long enough to cause a programming. In other words, the duration of application of the cell supply voltage must be chosen to be sufficiently short to be compatible with the use of a single supply voltage.

In the case where both voltages are used, Schmitt trigger 61 is supplied under voltage Vr.

As an alternative, the programming may be performed in a single step by providing additional transistors short-circuiting transistors 62G and 62D, respectively, to program the cell. Trigger 61 is then only used in read mode.

FIG. 8 illustrates an example of implementation of Schmitt trigger 61 of FIG. 7. Said trigger comprises two symmetrical structures in parallel between a current source 64 supplied by voltage Vp or Vr (terminal 1) and ground 2. Each structure comprises, between output terminal 65 of source 64 and the ground, a P-channel MOS transistor 66D or 66G, the respective gates of which form the inverting and non-inverting input terminals − and +, and the respective drains of which define the output terminals connected to the gates of transistors 62G and 62D. Each of terminals 62G and 62D is connected to ground 2 by a series association of two N-channel MOS transistors 67G, 68G and 67D, 68D. Transistors 67G and 67D are diode-assembled, their respective gates and drains being interconnected. The respective gates of transistors 68G and 68D are connected to the drains of transistors 67D and 67G of the opposite branch. An N-channel MOS transistor 69G or 69D, respectively, is assembled in a current mirror on transistors 67G and 67D. These transistors are connected between terminals 62D and 62G respectively and, via two N-channel MOS transistors 70G and 70D, to ground 2 to guarantee the hysteresis during the reading. The gates of transistors 70G and 70D receive a control signal CT, active only during the reading and turning off transistors 70G and 70D to avoid consumption in the amplifier after a reading.

The operation of a Schmitt trigger 61 such as illustrated in FIG. 8 is perfectly well known. As soon as an imbalance appears between the voltage level of one of the − or + inputs (gates of transistors 66D and 66G), this imbalance is locked due to the crossed current mirror structure of the low portion of the assembly.

FIG. 9 shows a third embodiment of a cell according to the present invention. Like the preceding memory cell, the cell of FIG. 9 has the advantage of locking a steady state enabling suppression of the permanent cell supply (power consumption) once the read state has been generated.

The actual cell MC comprises two parallel branches, each formed of a P-channel MOS transistor 81G, 81D, of a programming resistor RP1, RP2, of an N-channel MOS transistor 82G, 82D between a terminal 83 connected to read supply voltage Vr (terminal 1′) via a P-channel MOS transistor 84, and ground 2. Transistor 84 is intended to be controlled by a signal COM for supplying the structure in a reading. When off, no consumption is generated in the previously-described parallel branches. Signal COM is also sent to the gates of two N-channel MOS transistors 85G, 85D connected between the respective gates of transistors 81G and 81D and the ground. The gates of transistors 81G and 82G are interconnected to the drain of transistor 82D while the gates of transistors 81D and 82D are interconnected to the drain of transistor 82G, to stabilize the read state.

Terminals 4, 6 of resistors RP1 and RP2 opposite to transistors 82 are respectively connected, via P-channel selection MOS transistors MPS1 and MPS2, to output terminals BL and NBL of the cell. Optionally, terminals BL and NBL are connected via follower amplifiers or level adapters 86G and 86D generating logic state signals DATA and NDATA of bit lines of the structure. Selection transistors MPS1 and MPS2 are controlled by a signal ROW of memory cell selection in a column of the type shown in FIG. 4. With a simple reading of the cell, the previously-described structure effectively enables obtaining, on terminals BL and NBL, the programmed state of the cell identified by the value difference of resistances RP1 and RP2, minute though it may be. This difference is amplified and the cell state is stabilized due to its crossed structure.

The programming of a memory cell such as illustrated in FIG. 9 is performed by means of two programming transistors MPP1 and MPP2 (here, P-channel MOS transistors) having their respective drains connected to terminals S and NS (like in the preceding drawings), and the respective sources of which are intended to receive programming voltage Vp. The gates of transistors MPP1 and MPP2 receive signals Pg1 and Pg2. It should however be noted that, since P-channel MOS transistors are involved, the states of these signals must be reversed with respect to the previously-described structures using N-channel transistors.

Before cell selection, transistors MPS1 and MPS2 are both blocked by signal ROW. The structure is thus isolated.

A reading starts with the setting to the high state of signal COM which imposes a low level to all the nodes of the cell structure. When signal COM is reset, the gates of transistors 81D and 85D are charged through resistor RP1 while the gates of transistors 81G and 85G are charged through resistor RP2, the gate capacitances being equivalent by symmetry. Assuming that resistor RP1 exhibits the lowest value, the drain of transistor 82G has a greater voltage than the drain of transistor 82D. This reaction is amplified to provide a high level on terminal 4 and a low level on terminal 6. This operation is carried out only once as long as supply voltage Vr is maintained.

To be read from, the cell is selected by the setting to the high state of signal ROW. Transistors MPS1 and MPS2 are then turned on, which enables transferring the state of nodes 4 and 6 onto bit lines BL and NBL generating logic output signals DATA and NDATA.

To program the cell of FIG. 9, it is started from a state where selection transistors MPS1 and MPS2 are off. Signal COM is switched high to draw the respective drains of transistors 82G and 82D to ground. Since transistor 84 is off, any current leakage to supply Vr is impossible.

A sufficient voltage level (Vp) is then imposed by means of one of transistors MPP1 and MPP2 on terminal BL or NBL according to the resistor RP1 or RP2 which is desired to be programmed by irreversible decrease in its value. Then, transistors MPS1 and MPS2 are turned off by the switching of signal ROW. The programming voltage is immediately transferred onto the resistor to be programmed, while the opposite node NS or S remains floating.

The programming and read voltages may be different as will be discussed hereafter.

In the assembly illustrated in FIG. 9, associated with cell MC, the respective sources of transistors MPP1 and MPP2 are connected to the outputs of follower elements 87G and 87D supplied by programming voltage Vp. The respective inputs of follower elements 87G and 87D receive voltage Vp by means of a follower amplifier 88, the input of which receives a binary signal PRG for triggering a programming and the output of which is directly connected to the input of amplifier 87G and, via an inverter 89 supplied by voltage Vp, to the input of amplifier 87D. The function of inverter 89 is to select that of the branches to be submitted to voltage Vp according to the state of signal PRG. In this case, transistors MPP1 and MPP2 may be controlled by a same signal. In the absence of an inverter 89, separate signals Pg1 and Pg2 are used.

To avoid incidental inversion of the cell state when the selection transistors are on due to the precharge level on uncontrolled lines of the structure, two transistors, respectively 90G and 90D (here, N-channel MOS transistors), connecting lines BL and NBL, respectively, to ground, are provided. These transistors are simultaneously controlled by a combination of signals W and R respectively indicative by a high state of a write phase and of a read phase. These two signals are combined by an XNOR-type gate 91, the output of which crosses a level-shifting amplifier 92, supplied by voltage Vp, before driving the gates of transistors 90G and 90D. This structure enables drawing nodes BL and NBL to ground before each read operation.

The generation of the control signals of the structure of FIG. 9 is within the abilities of those skilled in the art based on the functional indications given hereabove.

FIG. 10 illustrates, in a very simplified partial perspective view, an embodiment of a polysilicon resistor of the type of programming resistors Rp1 and Rp2 according to the present invention.

Such a resistor (designated as 31 in FIG. 10) is formed of a polysilicon track (also called a bar) obtained by etching of a layer deposited on an insulating substrate 32. Substrate 32 is indifferently directly formed of the integrated circuit substrate or is formed of an insulating layer forming an insulating substrate or the like for resistor 31. Resistor 31 is connected, by its two ends, to conductive tracks (for example, metal tracks) 33 and 34 intended to connect the resistive bar to the other integrated circuit elements. The simplified representation of FIG. 4 makes no reference to the different insulating and conductive layers generally forming the integrated circuit. To simplify, only resistive bar 31 laid on insulating substrate 32 and in contact, by the ends of its upper surface, with the two metal tracks 33 and 34, has been shown. In practice, the connections of resistive element 31 to the other integrated circuit components are obtained by wider polysilicon tracks starting from the ends of bar 31, in the alignment thereof. In other words, resistive element 31 is generally formed by making a section of a polysilicon track narrower than the rest of the track. Resistance R of element 31 is given by the following formula:
R=σ(L/s),
where σ designates the resistivity of the material (polysilicon, possibly doped) forming the track in which element 31 is etched, where L designates the length of element 31, and where s designates its section, that is, its width l by its thickness e. Resistivity σ of element 31 depends, among others, on the possible doping of the polysilicon forming it.

Most often, upon forming of an integrated circuit, the resistors are provided by referring to a notion of so-called square resistance R_{□}. This square resistance defines as being the resistivity of the material divided by the thickness with which it is deposited. Taking the above relation giving the resistance of an element 31, the resistance is thus given by the following relation:
R=R_{□}*L/l.

Quotient L/l corresponds to what is called the number of squares forming resistive element 31. This represents, as seen from above, the number of squares of given dimension, depending on the technology, put side by side to form element 31.

The value of the polysilicon resistance is thus defined, upon manufacturing, based on the above parameters, resulting in so-called nominal resistivities and resistances. Generally, thickness e of the polysilicon is set by other manufacturing parameters of the integrated circuit. For example, this thickness is set by the thickness desired for the gates of the integrated circuit MOS transistors.

A feature of the present invention is to temporarily impose, in a polysilicon resistor (Rp1 or Rp2) of which the value is desired to be irreversibly decreased, a programming or constraint current greater than a current for which the resistance reaches a maximum value, this current being beyond the normal operating current range (in read mode) of this resistance. In other words, the resistivity of the polysilicon is decreased in the operating current range, in a stable and irreversible manner, by temporarily imposing in the corresponding resistive element the flowing of a current beyond the operating current range.

Another feature of the present invention is that the current used to decrease the resistance is, conversely to a fusible element, non-destructive for the polysilicon element.

FIG. 11 illustrates, with a curve network giving the resistance of a polysilicon element of the type shown in FIG. 10 according to the current flowing therethrough, an embodiment of the present invention for programming one of the memory cell resistors.

It is assumed that the polysilicon having been used to manufacture resistive element 31 (Rp1 or Rp2) exhibits a nominal resistivity giving element 31, for the given dimensions l, L, and e, a resistance value Rₙₒₘ. This nominal value of the resistance corresponds to the value taken in a stable manner by resistive element 31 in the operating current range of the system, that is, generally, for currents smaller than 100 μA.

According to the present invention, to decrease the value of the resistance and to switch in an irreversible and stable manner, for example, to a value R1 smaller than Rₙₒₘ, a so-called constraint current (for example, I1), greater than a current Im for which the value of resistance R of element 31 is maximum without for all this being infinite, is imposed across resistive element 31. As illustrated in FIG. 11, once current I1 has been applied to resistive element 31, a stable resistance of value R1 is obtained in range A1 of operating currents of the integrated circuit. In fact, curve Sₙₒₘ of the resistance according to the current is stable for relatively low currents (smaller than 100 μA). This curve starts increasing for substantially higher currents on the order of a few milliamperes, or even more (range A2). In this current range, curve Sₙₒₘ crosses a maximum for value Im. The resistance then progressively decreases. In FIG. 11, a third range A3 of currents corresponding to the range generally used to make fuses has been illustrated. These are currents on the order of one tenth of an ampere where the resistance starts abruptly increasing to become infinite. Accordingly, it can be considered that the present invention uses intermediary range A2 of currents between operating range A1 and destructive range A3, to irreversibly decrease the value of the resistance or more specifically of the resistivity of the polysilicon element.

Indeed, once the maximum of curve Sₙₒₘ of the resistivity according to the current has been passed, the value taken by the resistance in the operating current range is smaller than value Rₙₒₘ. The new value, for example, R1, depends on the higher value of the current (here, I1) which has been applied during the irreversible current phase. It should indeed be noted that the irreversible decrease performed by the present invention occurs in a specific programming phase, outside of the normal read operating mode (range A1) of the integrated circuit, that is, outside of the normal resistor operation.

If necessary, once the value of the polysilicon resistance has been lowered to a lower value (for example, R1 in FIG. 11), an irreversible decrease in this value may further be implemented. It is enough, to achieve this, to exceed maximum current I1 of the new curve S1 of the resistance according to the current. For example, the value of the current may be increased to reach a value I2. When the current is then decreased again, a value R2 is obtained for the resistor in its normal operating range. The value of R2 is smaller than value R1 and, of course, than value Rₙₒₘ. In the application to the memory cells of the preceding drawings, this can enable inverting the programming a limited number of times.

It can be seen that all the curves of the resistance according to the current join on the decrease slope of the resistance value, after having crossed the curve maximum. Thus, for a given resistive element (ρ, L, s), currents I1, I2, etc. which must be reached, to switch to a smaller resistance value, are independent from the value of the resistance (Rₙₒₘ, R1, R2) from which the decrease is caused.

What has been expressed hereabove as the resistance value corresponds in fact to a decrease in the resistivity of the polysilicon forming the resistive element. The present inventors consider that the crystalline structure of the polysilicon is modified in a stable manner and that, in a way, the material is reflowed, the final crystalline structure obtained depending on the maximum current reached. In fact, the constraint current causes a temperature rise of the silicon element, which causes a flow thereof.

Of course, it will be ascertained not to exceed parameterizing current range A2 (on the order of a few milliamperes) to avoid destroying the polysilicon resistor. This precaution will pose no problem in practice since the use of polysilicon to form a fuse requires much higher currents (on the order of one tenth of an ampere) which are not available once the circuit has been made.

The practical forming of a polysilicon resistor according to the present invention does not differ from the forming of a conventional resistor. Starting from an insulating substrate, a polysilicon layer is deposited and etched according to the dimensions desired for the resistor. Since the deposited polysilicon thickness is generally determined by the technology, the two dimensions which can be adjusted are the width and the length. Generally, an insulator is redeposited on the polysilicon bar thus obtained. In the case of an on-line interconnection, width l will have been modified with respect to the wider access tracks to be more strongly conductive. In the case of an access to the ends of the bar from the top as shown in FIG. 10, vias will be made in the overlying insulator (not shown) of the polysilicon bar to connect contact metal tracks 33 and 34.

In practice, to have the highest resistance adjustment capacity with a minimum constraint current, a minimum thickness and a minimum width will be desired to be used for the resistive elements. In this case, only length L conditions the nominal value of the resistance once the polysilicon structure has been set. The possible polysilicon doping, whatever its type, does not hinder the implementation of the present invention. The only difference linked to the doping is the nominal resistivity before constraint and the resistivities obtained for given constraint currents. In other words, for an element of given dimensions, this conditions the starting point of the resistance value, and accordingly the resistances obtained for given constraint currents.

To switch from the nominal value to a lower resistance or resistivity value, or to switch from a given value (smaller than the nominal value) to a still lower value, several methods may be used according to the present invention.

According to a first implementation mode, the current is progressively (step by step) increased in the resistor. After each application of a higher current, it is returned to the operating current range and the resistance value is measured. As long as current point Im has not been reached, this resistance will remain at value Rₙₒₘ. As soon as current point Im has been exceeded, there is a curve change (curve S) and the measured value when back to the operating currents becomes a value smaller than value Rₙₒₘ. If this new value is satisfactory, the process ends here. If not, higher currents are reapplied to exceed the new maximum value of the current curve. In this case, it is not necessary to start from the minimum currents again as when starting from the nominal resistance. Indeed, the value of the current for which the resistance will decrease again is necessarily greater than the value of constraint current I1 applied to pass onto the current curve. The determination of the step to be applied is within the abilities of those skilled in the art and is not critical in that it essentially conditions the number of possible decreases. The higher the step, the more the jumps between values will be high.

According to a second implementation mode, the different currents to be applied to pass from the different resistance values to smaller values are predetermined, for example, by measurements. This predetermination takes of course into account the nature of the polysilicon used as well as, preferentially, the square resistance, that is, the resistivity of the material and the thickness with which it is deposited. Indeed, since the curves illustrated by FIG. 11 may also be read as the curves of the square resistance, the calculated values may be transposed to the different resistors of an integrated circuit defined by the widths and lengths of the resistive sections. According to this second implementation mode, the value of the constraint current to be applied to the resistive element to decrease its value in an irreversible and stable manner can then be predetermined.

The two above embodiments may be combined.

According to the present invention, the irreversible decrease in the resistance or resistivity can be performed after manufacturing when the circuit is in its functional environment. In other words, control circuit 7 and the programming transistors described in relation with former figures can be integrated with the memory cell(s).

The curve change, that is, the decrease in the resistance value in normal operation is almost immediate as soon as the corresponding constraint current is applied. “Almost immediate” means a duration of a few tens or even hundreds of microseconds which are sufficient to apply the corresponding constraint to the polysilicon bar and decrease the value of its resistance. This empirical value depends on the (physical) size of the bar. A duration of a few milliseconds may be chosen for security. Further, it can be considered that, once the minimum duration has been reached, any additional duration of application of the constraint current does not modify, at least at the first order, the obtained resistance. Moreover, even if in a specific application, it is considered that the influence of the duration of application of the constraint cannot be neglected, the two preferred implementation modes (predetermining constraint values in duration and intensity, or step-by-step progression to the desired value) are perfectly compatible with the taking into account of the duration of application of the constraint.

As a specific example of embodiment, an N⁺ doped polysilicon resistor having a cross-section of 0.225 square micrometer (l=0.9 μm, e=0.25 μm) and a length L of 45 micrometers has been formed. With the polysilicon used and the corresponding doping, the nominal resistance was approximately 6,300 ohms. This corresponds to a square resistance of approximately 126 ohms (50 squares). By applying to this resistor a current greater than three milliamperes, a decrease in its value, stable for an operation under currents reaching 500 microamperes, has been caused. With a current of 3.1 milliamperes, the resistance has been lowered to approximately 4,500 ohms. By applying to the resistor a current of 4 milliamperes, the resistance has been decreased down to approximately 3,000 ohms. The obtained resistance values have been the same for constraint durations ranging from 100 microseconds to more than 100 seconds.

According to a particular implementation of the invention, the constraint current is comprised between 1 and 10 mA.

Always according to a particular implementation, the dopant concentration in the polycrystalline silicon is comprised between 1×10¹³ and 1×10¹⁶ atoms/cm³.

For example, polycrystalline silicon resistors have been made with the following nominal characteristics.

| | Polycrystalline silicon type | | | | | |
|---|---|---|---|---|---|---|
| | Crystalline | | Crystalline | | Amorphous | |
| Technology | 0.18 | μm | 0.18 | μm | 0.35 | μm |
| Width | 0.5 | μm | 0.5 | μm | 0.9 | μm |
| Length | 3.4 | μm | 80 | μm | 45 | μm |
| Thickness | 200 | nm | 200 | nm | 250 | nm |
| Resistance/ | 80 | Ohms/□ | 100 | Ohms/□ | 115 | Ohms/□ |
| square | | | | | | |
| Global | 556 | Ohms | 16.000 | Ohms | 5.750 | Ohms |
| resistance | | | | | | |
| Dopant | As = 6 × 10¹⁵ | | As = 5 × 10¹⁵ | | P = 1 × 10¹³ | |
| concen- | | | | | As = 4 × 10¹⁵ | |
| tration | | | | | | |
| (atoms/cm³) | | | | | | |
| Constraint | 5.5 | MA | 4.8 | mA | 2.75 | mA |
| current for | | | | | | |
| reducing by | | | | | | |
| one half the | | | | | | |
| resistor | | | | | | |

Of course, the above examples as well as the given orders of magnitude of currents and resistances for the different ranges concern present technologies. The currents of ranges A1, A2, and A3 may be different (smaller) for more advanced technologies and may be transposed to current densities. The principle of the present invention is not modified by this. There are still three ranges and the intermediary range is used to force the resistivity decrease.

Programming voltage Vp may be a variable voltage according to whether the programming current levels are predetermined or are unknown and must be obtained by a step-by-step increase.

According to an alternative embodiment, the programming current forced in resistor Rp1 or Rp2 is set by the control (gate voltage) of the corresponding programming transistor, voltage Vp being then fixed.

An advantage of the present invention is that a one-time programming memory cell can thus be formed in the same technology as conventional MOS transistors and with no additional step.

Another advantage of a memory cell according to the present invention over an EPROM cell is that it is not sensitive to ultraviolet rays.

The storage of a binary code in an integrated circuit by means of a one-time programming memory cell according to the present invention is preferably performed with a programming available on the finished integrated circuit, that is, the circuit in its application environment. This is made possible due to the relatively small currents required to program the memory cell resistors. However, this does not exclude a programming upon manufacturing. In this case, switch K and the programming control circuit are omitted. The possibility of programming the memory cell in its application environment is particularly advantageous and thus is a preferred embodiment of the present invention.

Another advantage of the present invention is that the irreversible modification of the value of the programmed resistor is not destructive and thus does not risk damaging other circuit parts. This especially enables providing a decrease in the resistance after manufacturing, and even during its lifetime in its application circuit.

Of course, for the storage of a word of several bits, as many memory cells as the word comprises bits are provided. The programming control circuit may then be common. In particular, a same signal may select the supply voltage of all memory cells in a programming phase. The control signals of the MOS programming transistors must however remain individualized to enable differentiating states 0 and 1 thereof according to the different cells. The forming of a control circuit is within the abilities of those skilled in the art based on the functional indications given hereabove.

Initially, resistors Rp1 and Rp2 being identical, the read state before programming is undetermined. This is however not disturbing for the use of a one-time programming memory.

The implementation of the present invention in fact enables programming several times a same memory cell without for all this enabling an infinite number of programming operations. Indeed, if too low a stable resistance is not forced upon first programming, the programming can still be inverted by decreasing the value of the programmable resistor of the other branch to a still smaller level.

FIG. 12 very schematically shows in the form of blocks an example of an exploitation circuit of a network of one-time programming memory cells 10 according to the present invention. In this example, the presence of n memory cells of the type illustrated in FIGS. 1, 2, 3, 4, or 9 is assumed. A central processing unit (CPU) 11 receives a memory configuration signal, either in programming (PG), or in use (USE). For a programming, a random generator (RNG) 12 providing n bits to memory cell network 10 is for example used. In other words, random generator 12 provides the binary code to be written by programming of the different cells according to the present invention. In use, central processing unit 11 starts a reading (READ) of circuit 10. Circuit 10 then provides a binary word ID, for example of identification of the integrated circuit chip containing the memory cells. In such an application of integrated circuit chip identifier storage, the use of one-time programming memory cells according to the present invention has many advantages.

A first advantage is the self-generation, within the integrated circuit chip, of its identifier, which avoids any risk of leaks by human intervention.

Another advantage of the present invention is that the random character of the stored identification word completely depends on random generator 12 and no longer, as in some conventional applications, on a physical parameter network.

Another advantage of the present invention is that the stored code no longer depends, in its content, on any software code. The system security against possible piracies is thus improved.

Another advantage of the present invention is that the number of extraction cycles is not limited.

For the programming of a memory according to the present invention, several different phases may be dissociated in the product lifetime. For example, a first area (first series of resistors) programmable at the end of the manufacturing to contain a “manufacturer” code is provided. The rest of the memory is left available to be programmed (at one go or in several goes) by the user (final or not).

Another example of application of the present invention relates to the locking of an integrated circuit after detection of a fraud attempt. Fraud attempt detection processes are perfectly well known. They are used to identify that an integrated circuit chip (for example, of prepaid or not smart card type) has been attacked for, either using the prepaid units, or discovering a secret key of the chip. In such a case, the subsequent chip operation is desired to be invalidated to avoid for the fraud to be successful. By implementation of the present invention, it is possible to memorize a secret quantity by means of a one-time programming memory specific to the present invention. If, during the integrated circuit lifetime, a fraud attempt justifying the chip disabling is detected, the programming of one or several memory cells in an inverse state is automatically caused. By inverting even a single bit of the secret quantity, the system will no longer be able to properly identify the chip, which results in a full and irreversible locking of the chip.

According to another example of application, a one-time programming memory cell of the present invention is used to lock an integrated circuit chip in a specific operating mode, for example, after a limited number of uses, or to impose a counter progression direction.

It should be noted that the present invention is easily transposable from one technology to another.

Of course, the present invention is likely to have various alterations, modifications, and improvement which will readily occur to those skilled in the art. In particular, the practical implementation of the polysilicon programming resistors is within the abilities of those skilled in the art based on the functional indications given hereabove.

Further, the present invention applies to a parallel reading of several cells as well as to a series reading. Adapting the control circuit is within the abilities of those skilled in the art.

1. A binary value memory cell, comprising:
two parallel branches, each comprising a polysilicon programming resistor made of polysilicon connected between a first supply terminal (1; 2) and a differential cell state read point or terminal; and
at least one first switch connecting, during programming, one of said read terminals to a second supply terminal.

2. The memory cell of claim 1, wherein each branch comprises a first switch connecting, during a programming, the read terminal of the branch to said second supply terminal.

3. A binary value memory cell, comprising:
two parallel branches, each comprising, in series between two supply voltage terminals, a programming resistor in polysilicon, and a fixed resistor, the fixed resistors of the two branches being, preferentially, identical;
a differential amplifier, the respective inputs of which are connected to the central points between the resistors of each branch constituting differential reading points of the cell state, the output of the amplifier providing the binary value stored in the cell; and
at least a first switch short-circuiting, during programming, one of said fixed resistors.

4. A binary value memory cell, comprising:
two parallel branches, each comprising, in series between two supply voltage terminals, a programming resistor made of polysilicon, a first transistor and a second transistor, the junction between the resistor and the first transistor defining a direct or reverse read terminal of the binary value stored in the cell, the gates of the second transistors receiving a cell selection signal, and the gate of the first transistor of each branch being connected to the read point of the other branch; and
at least a first switch connecting, during programming, one of said read terminals to one of said supply voltage terminals.

5. A binary value memory cell, comprising:
two parallel branches, each comprising, in series between a first supply terminal and a differential read point or terminal of the state of the cell, a programming resistor in polysilicon, and a first transistor, two first switches connecting each of said respective read terminals to a second supply voltage terminal.

6. A binary value memory cell, comprising:
two parallel branches, each comprising, in series between two supply voltage terminals, a first transistor, two programming resistors in polysilicon, and a second transistor, the gate of the second transistor of each branch being connected to the interconnection between one of the terminals and the second transistor of the other branch;
a differential amplifier, the two respective inputs of which are connected to the junction between the resistors of each branch and two inverted outputs of which are respectively connected to the gates of the first transistors; and
at least a first switch short-circuiting, during a programming, one of said second transistors.

7. A memory cell according to claim 1, wherein one of the supply voltage terminals is connected, through a selector, to at least two supply voltages, among which a read supply voltage relatively low and a programming supply voltage relatively high.

8. A binary value memory cell, comprising:
two parallel branches, each comprising, in series between a first read voltage terminal and a reference potential terminal, a first transistor, a programming resistor made of polysilicon, and a second transistor, the junction between the resistor and the first transistor of each branch defining a read point of the differential state of the cell connected to the gates of the transistors of the other branch; and
at least two first switches for applying, during a programming, a programming potential to one of said read terminals.

9. The cell of claim 8, wherein the second switches for selection are inserted between said read points and the respective first switch connected thereto.

10. The cell of claim 6, wherein a supply switch connects said first terminal to a read voltage supply terminal for interrupting the power consumption of the cell once the state is generated.

11. The cell of claim 6, wherein third two transistors connect the gates of the first and second transistors of the respective terminals to the reference potential terminal, for stabilizing the generated state.

12. The cell of claim 10, wherein said supply switch and said third transistors are simultaneously controlled.

13. The memory cell of claim 1, wherein said programming resistors have the same size and the same possible doping.

14. The memory cell of claim 1, wherein the programming is made by reducing, in an irreversible and stable way within the operation read current range of the cell, the value of one of the programming resistors by flowing a current in one of the resistors made of polysilicon that is higher than the current for which the value of said resistor has a maximum, the programming being not destructive of said resistor.

15. A one-time programming memory comprising a plurality of memory cells according claim 1, the various cells sharing the same first switches.

16. A method for programming a memory cell according to claim 1, comprising temporarily flowing, in one of said branches selected by one of the first switches, a current higher than the current for which the value of the programmation resistor of the relative branch has a maximum.

17. The method of claim 15, comprising the steps of:
increasing step by step the current in the programming resistor selected by the programming switch of one of the branches; and
measuring, after each application of a greater current, the value of this resistance in its functional read environment.

18. The method of claim 16, comprising using a predetermined table of correspondence between the programming current and the desired final resistance to apply to the selected programming resistor the adapted programming current.

19. The cell of claim 8, wherein a supply switch connects said first terminal to a read voltage supply terminal for interrupting the power consumption of the cell once the state is generated.

20. The cell of claim 8, wherein third two transistors connect the gates of the first and second transistors of the respective terminals to the reference potential terminal, for stabilizing the generated state.

21. The cell of claim 20, wherein said supply switch and said third transistors are simultaneously controlled.
